(19) United States
(12) Patent Application Publication
(10) Pub. No.: US 2021/0159885 A1
(43) Pub. Date: May 27, 2021

(54) ELECTROACOUSTIC RESONATOR, RF FILTER WITH INCREASED USABLE BANDWIDTH AND METHOD OF MANUFACTURING AN ELECTROACOUSTIC RESONATOR

(71) Applicant: RF360 EUROPE GMBH, Munchen (DE)

(72) Inventors: Christian HUCK, Munchen (DE); Marcus MAYER, Taufkirchen (DE)

(21) Appl. No.: 17/047,664

(22) PCT Filed: Mar. 18, 2019
(86) PCT No.: PCT/EP2019/056686

§ 371 Date: Oct. 14, 2020

(30) Foreign Application Priority Data
Apr. 19, 2018 (DE) 10 2018 109 346.2

(51) Int. Cl. H03H 9/25; H03H 9/145; H03H 9/02; H03H 9/64; H03H 3/08

(52) U.S. Cl. CPC H03H 9/25; H03H 9/145; H03H 3/08; H03H 9/6406; H03H 9/02543

(57) ABSTRACT

An electroacoustic resonator (EAR) that allows RF filters in which transversal modes are suppressed in a wider frequency range and corresponding RF filters and methods are provided. The resonator has an electrode structure (BB,EF) on a piezoelectric material and a transversal acoustic wave guide. The wave guide has a central excitation area (CEA), trap stripes (TP) and barrier stripes (B). The difference in wave velocity (|VCEA−VB|) between the central excitation area and the barrier stripes determines the frequency range of suppressed transversal modes.

The present invention refers to electroacoustic resonators, e.g. for RF filters for mobile communication devices, to RF filters with an increased usable bandwidth and to methods of manufacturing such resonators.

Electroacoustic resonators employ acoustic waves and have a piezoelectric material and an electrode structure attached to the piezoelectric material. Electroacoustic resonators can be combined to build RF filters to select wanted RF signals from unwanted RF signals. The performance of RF filters depends on the performance of the electroacoustic resonators. It is desired that an RF filter has a low insertion loss within a passband and a high insertion attenuation outside a passband. Further, it is preferred that passband skirts between a passband and frequency ranges of high attenuation have a steep transition between the frequency ranges.

SAW resonators (SAW=surface acoustic wave) establish one type of electroacoustic resonators. SAW resonators have interdigitated comb-like electrode structures with electrode fingers that are connected to one of two opposite bus bars to convert between RF signals and acoustic waves. Wanted wave modes propagate along the longitudinal direction which is oriented within the surface of the corresponding piezoelectric material and which is mainly perpendicular to the extension direction of the electrode fingers. Correspondingly, the electrode fingers extend towards the transversal direction.

Although wanted wave modes propagate along the longitudinal direction, it is possible that acoustic waves propagate in a direction which deviates from the longitudinal direction due to wave diffraction. This may result in transversal modes degrading the performance of a resonator.

To reduce losses due to emission of acoustic waves in a transversal direction (i.e. to reduce transversal losses), it is possible to establish an acoustic wave guide. Usually, an acoustic wave guide is established by providing features, e.g. transversal gaps, at the surface of the piezoelectric material that affects the propagation of acoustic waves at the surface. However, due to wave diffraction it is possible that the generation of transversal modes is a result of an acoustic wave guide that was established to reduce transversal losses.

Transversal modes can be reduced or eliminated when a piston mode is employed. Technical means for establishing a piston mode are known from US 2013/0051588 A: The creation of an acoustic velocity profile in a transversal direction supports the excitation of a piston mode.

However, it was found that the means stated in US 2013/0051588 A1 are effective within a certain frequency range only.

The trend towards the use of more and more frequency ranges and increasing bandwidths for wireless communication systems demands for RF filters providing bandpass filters with a wider bandwidth.

Thus, it is further desired to have an RF filter that provides a passband with an increased bandwidth without pronounced ripples.

Another means to minimize transversal modes is aperture weighting. However, aperture weighting does not eliminate transversal modes but only smears out transversal modes.

Further, slanted acoustic tracks can be used. However, the use of slanted acoustic tracks also leads to transversal modes, the effects of which are just smeared out but which are not eliminated.

Correspondingly, it is an object to provide an RF filter with a good filter performance, with reduced or eliminated transversal modes and with an increased bandwidth. Further, corresponding electroacoustic resonators for establishing such filters are also needed.

To that end, an electroacoustic resonator, an RF filter and a method of manufacturing an electroacoustic resonator according to the independent claims are provided. Dependent claims provide preferred embodiments.

The electroacoustic resonator that allows bandpass filters having an increased bandwidth without passband ripples comprise a piezoelectric material and an electrode structure on the piezoelectric material. Further, the resonator has a transversal acoustic wave guide having a central excitation area, trap stripes flanking the central excitation area and barrier stripes flanking the trap stripes.

The resonator has a wave velocity VCEA in the central excitation area, a wave velocity VTP in the trap stripes and a wave velocity VB in the barrier stripes.

For a given frequency bandwidth Δf of transversal mode suppression, a velocity difference ΔV=abs(VB−VCEA), and a wavelength the following applies:

0.5≤ΔV/(Δf*λ)≤1.5

where ΔV=abs (VB−VCEA).

Further, it is possible that 0.9≤ΔV/(Δf*λ)≤1.1 or that ΔV/(Δf*λ)=1.

In case of a convex slowness the transversal modes arise above resonance frequency demanding for VB>VCEA, whereas in case of a concave slowness the transversal modes arise below resonance frequency demanding for VB<VCEA.

Correspondingly, for a convex and a concave slowness the following condition

0.5≤ΔV/(Δf*λ)≤1.5

determines the required velocity difference ΔV to obtain a specific frequency bandwidth Δf of transversal mode suppression.

In the electroacoustic resonator the trap stripes denote areas that extend along the longitudinal direction next to areas that extend along the longitudinal direction and that are arranged next to the trap stripes. Thus, one trap stripe is arranged between one barrier stripe and the central excitation area. The other trap stripe is arranged between the other barrier stripe and the central excitation area on the other side of the acoustic track. The two barrier stripes are terminated by the areas of the busbars.

Thus, a transversal velocity profile is provided that allows an increased bandwidth without transversal modes due to the increased velocity difference of the velocities in the central excitation area and in the barrier stripes, respectively.

The terms “concave slowness” and “convex slowness” are defined, e.g., in US 2013/0051588 A1. In particular, the type of slowness depends on the anisotropy factor. If the anisotropy factor γ is larger than −1 then the slowness is a convex slowness. If the anisotropy factor γ is smaller than −1 then the slowness is a concave slowness. The anisotropy factor γ is also defined in US 2013/0051588 A1.

Thus, for a given desired bandwidth the above equations define the necessary velocity difference between the velocity in the central excitation area and the velocity in the barrier stripe for different types of substrates.

Correspondingly, RF filters based on such resonators can be established in which the bandwidth can be tailored such that present or future bandwidth requirements can be complied with.

The corresponding bandwidth Δf in this case defines the width of the frequency range in which disturbances caused by transversal modes are not only smeared out or reduced but eliminated.

It is possible that ηCEA is the metallization ratio in the central excitation area, ηTP is the metallization ration in the trap stripes and/or ηB is the metallization ratio in the barrier stripes. The number of different values selected ηCEA, ηTP and/or ηB can 1, 2 or 3.

In particular, it is possible that ηTP≠ηCEA.

The metallization ratio η of an interdigitated comb-like electrode structure is defined by the ratio: finger width/(finger width plus distance to an adjacent finger). A higher metallization ratio η means that electrode fingers are thicker (their extent along the longitudinal direction is larger) for a given distance between centers of adjacent electrode fingers. A larger metallization ratio generally causes a larger mass loading of the electrode structure on the piezoelectric material.

Generally, the acoustic velocity depends on the mass loading and stiffness parameters of the material arranged on the piezoelectric material. An increased mass loading may cause a reduced or increased acoustic velocity. Matter deposited on the piezoelectric material having higher stiffness parameters such as Young's modulus generally result in an increase of the wave velocity. At a specific mass loading where mass loading dominates over stiffness influence, further increasing the mass loading reduces the wave velocity.

Thus, generally two means exist for locally adjusting the wave velocity of acoustic waves propagating along the longitudinal direction: to increase or reduce the local mass loading and to reduce or increase stiffness parameters of matter arranged on the piezoelectric material.

Correspondingly, varying the metallization ratios in the central excitation area, in the trap stripes, and/or the barrier stripes provides the possibility of reducing or increasing the wave velocity in each area and relatively to each other, especially with reference to the central excitation area.

Thus, a wave guide with a reduced or increased acoustic velocity in the trap stripes and/or the barrier stripes with respect to the velocity of the central excitation area can be provided.

It is possible that the resonator comprises a dielectric material deposited in the central excitation area, in the area of the trap stripes and/or in the area of the barrier stripes.

The provision of the dielectric material is a means to vary the mass loading locally and to vary the stiffness parameters locally.

Depending on the thickness of a corresponding layer and of the stiffness parameters of the layer's material and of the density of the material, the acoustic velocity in the three velocity regions can be manipulated such that the preferred transversal profile of longitudinal velocities can be obtained.

It is possible that the dielectric material comprises a silicon nitride such as Si₃N₄, a silicon oxide such as a silicon dioxide, such as SiO₂, and/or an aluminium oxide, e.g. Al₂O₃, a hafnium oxide, e.g. HfO₂, or doped versions thereof.

Silicon nitride has high stiffness parameters. Thus, silicon nitride deposited in an area of the acoustic track generally increases the wave velocity until a specific thickness.

It is possible that the height of the electrode structures is hCEA in the central excitation area, hTP in the area of the trap stripes and hB in the area of the barrier stripes.

The number of different values selected from hCEA, hTP and hB can be 1, 2 or 3.

In particular, it is possible that hCEA≠hTP, hCEA≠hB and/or hTP≠hB.

Also, it is possible that hCEA=hTP and/or hCEA=hB and/or hTP=hB.

The height in the central excitation area can be different from the height in the trap stripes. The height in the central excitation area can be different from the height in the barrier stripes. Further, the height in the trap stripes can be different from the height in the barrier stripes.

As discussed above, different heights of the electrode structures provide different mass loading in the corresponding areas. The different mass loading in the corresponding areas can be used to add corresponding contributions to the tailored transversal velocity profile.

Such a transversal velocity profile can be used in the resonator to establish a piston mode. Correspondingly, a resonator is provided that can work with a piston mode.

The definition of a piston mode is contained in US 2013/0051588 A1.

It is possible that the piezoelectric material comprises lithium tantalate (LiTaO₃), lithium niobate (LiNbO₃), quartz or a lanthanum gallium silicate. The materials of the group of lanthanum gallium silicates are also known as langasites.

Lanthanum gallium silicates have the chemical formula A₃BC₃D₂O₁₄. A, B, C and D indicate particular cation sites.

Whether the resonator's piezoelectric material has a convex slowness or a concave slowness depends on several parameters, e.g. the material's composition, cut angles.

It is possible that the piezoelectric material is selected from a piezoelectric substrate, a piezoelectric monocrystalline substrate, a thin film. The thin film can be provided utilizing thin film deposition techniques or thin film substrate techniques, e. g. the transfer technique referred to as “Smart Cut”.

It is possible to establish an RF filter that comprises one or more resonators as stated above.

The resonators can be provided in a ladder-type like configuration. Thus, series resonators can be electrically connected in series in a signal path. Parallel resonators can be electrically connected in parallel paths electrically connecting the signal path to ground. The ladder-type like configuration can have a plurality of two or more ladder-type like elements that are cascaded along the signal direction. Each element has a series resonator in the signal path and a parallel resonator in a parallel path.

Bandpass filters and band rejection filters, respectively, can be obtained if the resonance frequency of a series mainly equals the anti-resonance frequency of a parallel resonator and vice versa.

A method for manufacturing an electroacoustic resonator can comprise the steps:
defining a bandwidth Δf of transversal mode suppression,
providing a piezoelectric material,
depositing electrode structures on the piezoelectric material and forming a transversal acoustic wave guide for surface acoustic waves at the surface on the piezoelectric material, the wave guide having a central excitation area wherein
the wave guide provides a wave velocity VCEA in the central excitation area,
the wave guide provides a wave velocity VTP in trap stripes flanking the central excitation area,
the wave guide provides a wave velocity VB in barrier stripes flanking the trap stripes.

For the given frequency bandwidth Δf of transversal mode suppression, VB and VCES are chosen such that

0.5≤ΔV/(Δf*λ)≤1.5

where ΔV=abs(VB−VCEA) and A is the wavelength of the resonator.

It is possible that for each additional megahertz of bandwidth an increase of the acous¬tic velocity difference of abs(VB−VCEA) by 2 m/s is provided. Thus, for a bandwidth of 200 MHz a velocity difference of 400 m/s is re¬quired. For a bandwidth of 400 MHz a velocity difference of 800 m/s is required. For a bandwidth of 600 MHz a velocity difference of 1200 m/s is required. Thus, the desired band¬width and the necessary velocity difference have a linear re¬lationship, e.g. for a transducer structure with a pitch p=λ/2.

Central aspects of the resonator and details of preferred embodiments are described in the accompanying schematic figures.

In the figures:

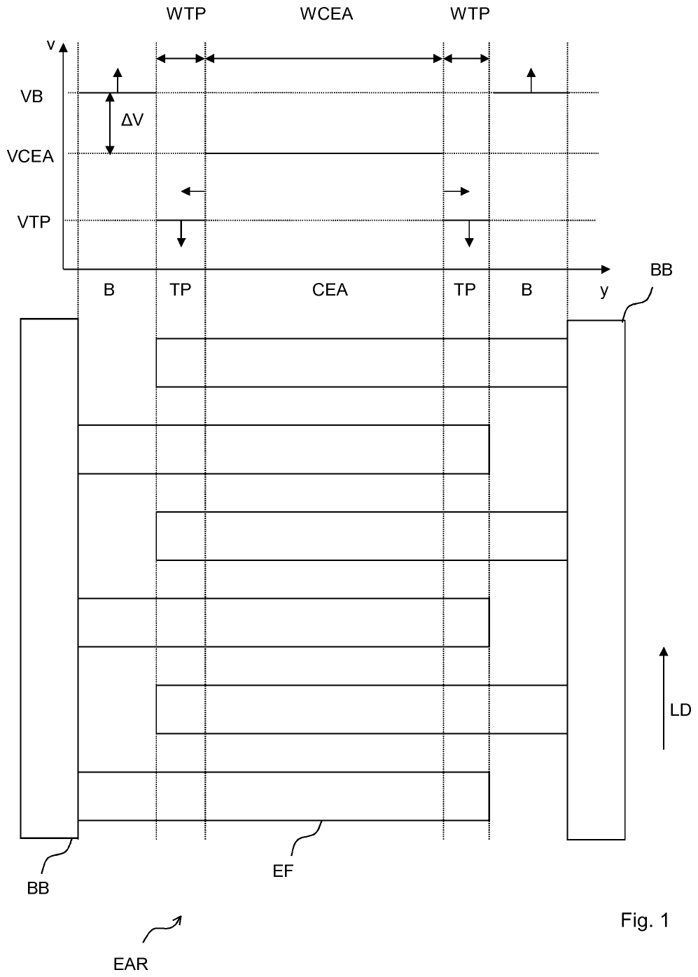

FIG. 1 shows a basic overview over the geometric arrangement and the correspondence between the geometric arrangement of the resonator and the transversal velocity profile;

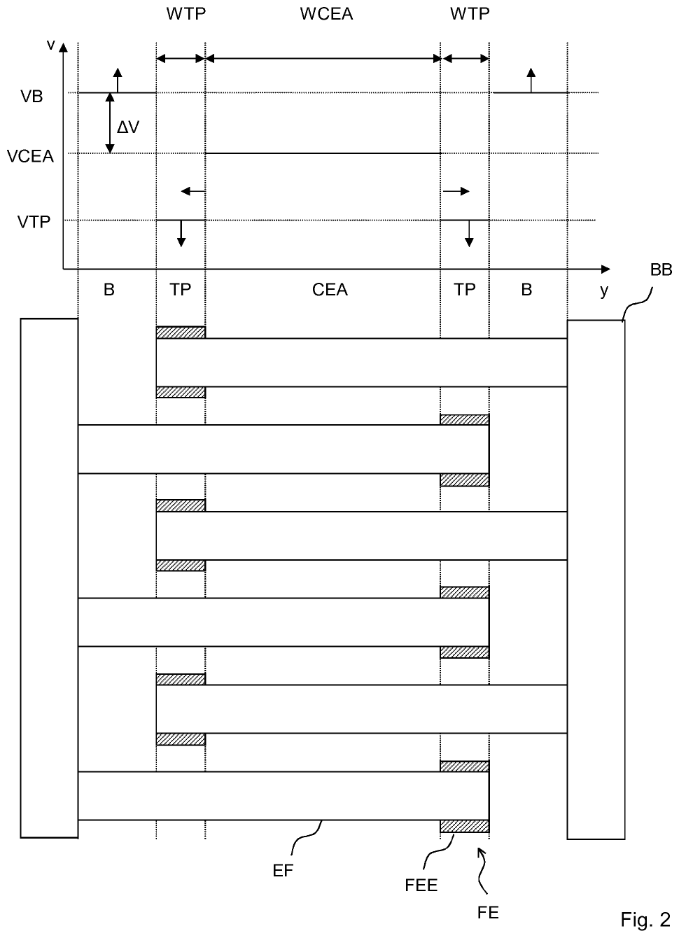

FIG. 2 illustrates the use of locally increased finger widths at the finger's end;

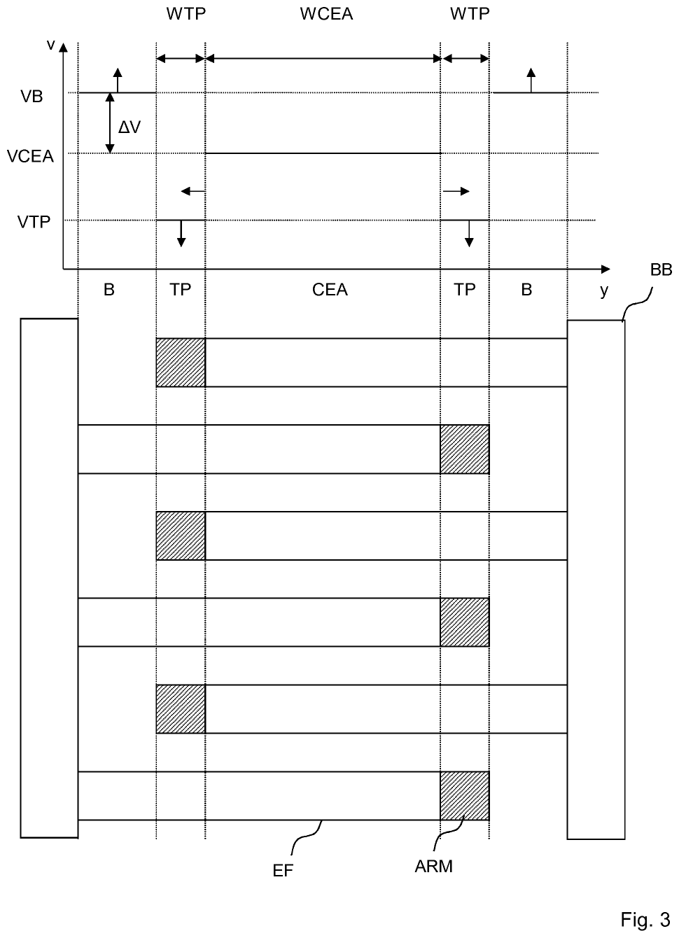

FIG. 3. Illustrates the use of locally different metallization heights;

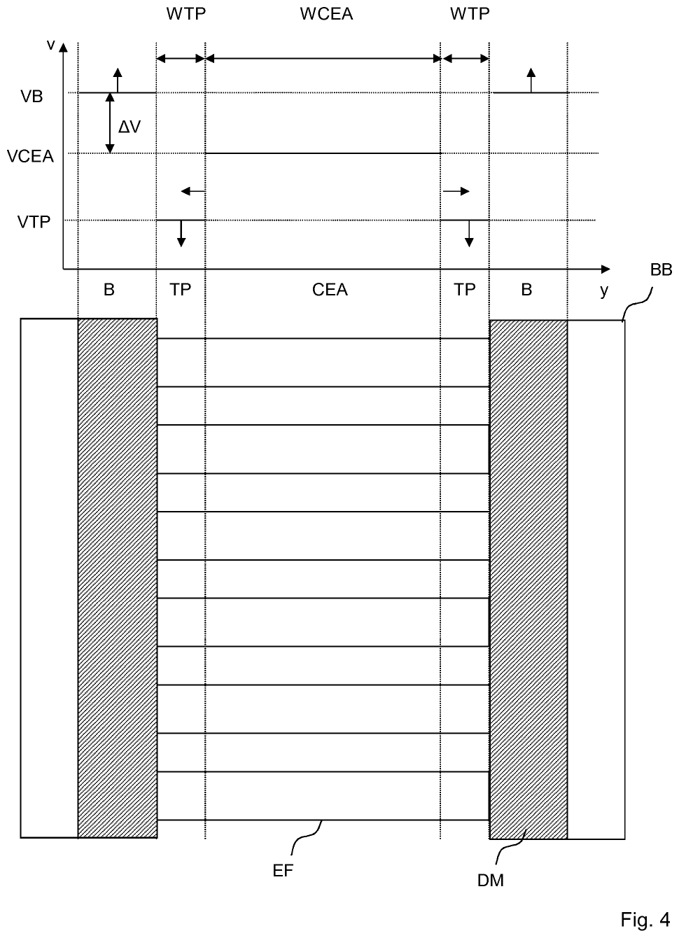

FIG. 4 illustrates the use of the dielectric material deposited on the electrode structure;

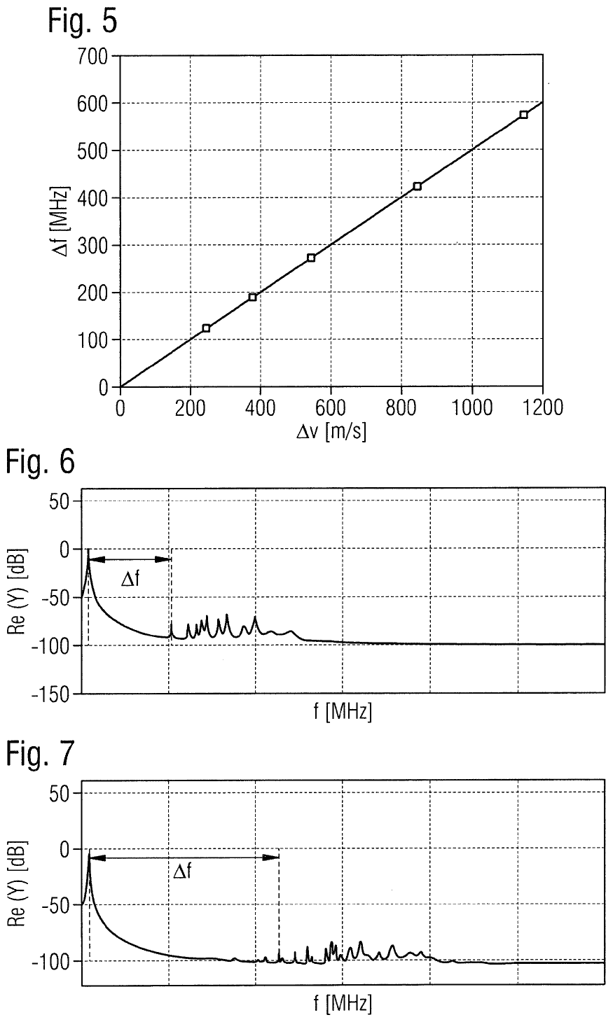

FIG. 5 illustrates the linear relationship between the velocity difference and the obtainable frequency bandwidth;

FIG. 6 illustrates the suppression of transversal modes in a narrow frequency bandwidth;

FIG. 7 illustrates the suppression of transversal modes in a wide frequency bandwidth.

The bottom part of FIG. 1 illustrates a segment of an electroacoustic resonator EAR that extends along the longitudinal direction LD that is perpendicular to the transversal direction Y. The electroacoustic resonator EAR has two busbars BB and electrode fingers EF. Each electrode finger EF is electrically connected to one of the two busbars BB. In a central excitation area CEA the electrode fingers convert between RF signals and acoustic waves. The central excitation area CEA is flanked by two trap stripes TP. The central excitation area CEA and the trap stripes TP extend along the longitudinal direction LD and are arranged one next to another. Further, the trap stripes TP are flanked by barrier stripes B which also extend along the longitudinal direction LD. In the trap stripes TP the finger ends of the electrode fingers EF are electroacoustically active and take place in the process of converting between RF signals and acoustic waves.

In each barrier stripe B only finger segments of electrode fingers EF that are electrically connected to one busbar BB are present. Thus, in the area of the barrier stripes B no acoustic waves are excited.

The wave velocity in the central excitation area CEA is VCEA. The wave velocity in the trap stripes TP is VTP. The wave velocity in the barrier stripes B is VB. The difference ΔV of the wave velocities in the central excitation area CEA and in the barrier stripes B, respectively, is ΔV=abs (VB−VCEA). In this context, the function abs denotes the absolute value of the difference.

It was found that a suppression of transversal modes in an increased frequency range can be obtained when ΔV is increased according to the above-stated equations. When ΔV is increased, it was found that it is preferred to reduce the width and the velocity of the trap stripes to establish a piston mode with increased bandwidth. The width of the trap stripes is denoted as WTP. The width of the central excitation area CEA is denoted as WCEA in FIG. 1.

As stated above, the velocity profile shown in the upper part of FIG. 1 is obtained by applying means for increasing or reducing the wave velocity locally. The wave velocity can be manipulated by manipulating the stiffness parameters of mat¬ter deposited on the piezoelectric material and by manipulat¬ing the mass loading on the piezoelectric material.

FIG. 2 shows the possibility of increasing the finger width at the corresponding finger ends FE of the electrode fingers EF. To that end finger end extensions FEE can be attached to the finger ends FE to increase the extension of the fingers in the longitudinal direction resulting in a larger metallization ratio in the finger end regions.

The finger end extensions establish a means to manipulate the wave velocity in the trap stripes. The increased finger width is compatible with the conventional means for depositing and structuring the material of the electrode structures.

The material of the finger end extension can be equal to the material of the electrode finger EF. However, it is possible that the material of the finger end extension differs from the material of the electrode fingers.

The finger end extensions establish a means applicable in the lateral surface plane of the resonator.

In contrast, FIG. 3 illustrates the possibility of increasing or reducing the metallization height of the electrode fingers locally. Thus, FIG. 3 illustrates a means active in a direction orthogonal to the lateral surface plane. Material of the finger ends FE can be removed to reduce the thickness in the height direction. However, it is also possible to add further matter on the finger ends FE to increase the mass loading and/or to manipulate the stiffness parameters in the trap stripes.

The material of the correspondingly added segments can be equal to the material of the electrode fingers EF. However, it is also possible that the material differs.

FIG. 4 illustrates the possibility of providing additional material in the barrier stripes B. The additional material can be provided as single strips extending along the longitu¬dinal direction. In order to avoid a short circuit of elec¬trode fingers it is preferred that the dielectric material has the necessary dielectric constant and low electrical conductivity.

The additional dielectric material increases the local mass loading in the barrier stripes.

Depending on the stiffness parameters of the dielectric material the local wave velocity can be increased or reduced.

The technical means for manipulating the local wave velocity between the busbars explained above and shown in the figures can be combined to obtain a tailored transversal velocity profile. However, it is also possible that some of the shown measures for adjusting the wave velocity are realized while others are not.

FIG. 5 shows the linear relationship between a desired fre¬quency bandwidth Δf of transversal mode suppression and the necessary difference in acoustic ve¬locity ΔV=abs(VB−VCEA) between the velocity in the barrier stripe VB and the velocity in the central excitation area VCEA for a transducer structure having a pitch p=λ/2.

FIG. 6 illustrates the frequency dependent real part of the complex admittance Y for a resonator in which transversal modes are suppressed in a rather narrow frequency range Δf at a lower acoustic velocity difference ΔV.

In contrast, FIG. 7 shows the real part of the complex ad¬mittance of a resonator where the acoustic velocity difference ΔV between the velocity in the barrier stripes and the velocity in the trap stripes is higher and adjusted such that a wider frequency range Δf without the excitation of transversal modes is obtained.

The resonator, the filter and the method for manufacturing a resonator are not limited to the technical details described above and shown in the drawings. In the acoustic track fur¬ther stripes extending along the longitudinal direction hav¬ing a specific wave velocity and a corresponding transversal velocity profile having more velocity sections along the transversal direction is possible.

### LIST OF REFERENCE SIGNS

ARM: added or removed matter
B: barrier stripe
BB: busbar
CEA: central excitation area
DM: dielectric material
EAR: electroacoustic resonator
EF: electrode finger
FE: finger end
FEE: finger end extension
LD: longitudinal direction
TP: trap stripe
V: wave velocity
VB: wave velocity in the barrier stripes
VCEA: wave velocity in the central excitation area
VTP: wave velocity in the trap stripes
WCEA: width of the central excitation area
WTP: width of a trap stripe
Y: admittance of resonator
ΔV: abs (VB−VTP)

1. An electroacoustic resonator for bandpass filters having an increased bandwidth, the resonator comprising
a piezoelectric material,
an electrode structure on the piezoelectric material,
a transversal acoustic wave guide having a central excitation area, trap stripes flanking the central excitation area and barrier stripes flanking the trap stripes,
wherein
the wave velocity is VCEA in the central excitation area,
the wave velocity is VTP in the in the trap stripes,
the wave velocity is VB in the in the barrier stripes,
and 0.5≤ΔV/(Δf*λ)≤1.5 for a desired band width Δf
and ΔV=abs (VB−VCEA).

2. The resonator of claim 1, where
0.9≤ΔV/(Δf*λ)≤1.1 or
ΔV/(Δf*λ)=1.

3. The resonator of any one of the claims 1-2 where
in case of a convex slowness: VB>VCEA and
in case of a concave slowness: VB<VCEA.

4. The resonator of any one of the claims 1-3, wherein ηCEA is the metallization ratio in the central excitation area, ηTP is the metallization ration in the trap stripes and/or ηB is the metallization ratio in the barrier stripes and
the number of different values selected ηCEA, ηTP and/or ηB is 1, 2 or 3.

5. The resonator of any one of the claims 1-4, wherein ηCEA is the metallization ratio in the central excitation area, ηTP is the metallization ration in the trap stripes and ηTP≠ηCEA.

6. The resonator of any one of the claims 1-5 further comprising a dielectric material deposited in the central excitation area, in the area of the trap stripes and/or in the area of the barrier stripes.

7. The resonator of claim 6, wherein the dielectric material comprises a silicon nitride such as Si₃N₄, a silicon oxide such as a silicon dioxide, such as SiO₂, and/or an aluminium oxide, e.g. Al₂O₃, a hafnium oxide, e.g. HfO2, or doped versions thereof.

8. The resonator of any one of the claims 1-7, wherein
the height of the electrode structure is hCEA in the central excitation area, hTP in the area of the trap stripes and hB in the area of the barrier stripes, and
the number of different values selected from hCEA, hTP and hB is 1, 2 or 3.

9. The resonator of any one of the claims 1-8, wherein the height of the electrode structure is hCEA in the central excitation area, hTP in the area of the trap stripes and hB in the area of the barrier stripes,
wherein hCEA≠hTP, hCEA≠hB and/or hTP≠hB.

10. The resonator of any one of the claims 1-9, which can work with a piston mode.

11. The resonator of any one of the claims 1-10, wherein the piezoelectric material comprises LiTaO₃, LiNbO₃, Quartz or a Lanthanum gallium silicate.

12. The resonator of any one of the claims 1-1 where the piezoelectric material is selected from a piezoelectric substrate, a piezoelectric monocrystalline substrate, a thin film.

13. An RF filter comprising one or more resonators of any one of the claims 1-12.

14. A Method for manufacturing an electroacoustic resonator, comprising the steps:
defining a bandwidth Δf of transversal mode suppression,
providing a piezoelectric material,
depositing electrode structures on the piezoelectric material and forming a transversal acoustic wave guide for surface acoustic waves at the surface on the piezoelectric material, the wave guide having a central excitation area wherein
the wave guide provides a wave velocity VCEA in the central excitation area,
the wave guide provides a wave velocity VTP in trap stripes flanking the central excitation area,
the wave guide provides a wave velocity VB in barrier stripes flanking the trap stripes where
for the given frequency bandwidth Δf of transversal mode suppression, VB and VCES are chosen such that
0.5≤ΔV/(Δf*λ)≤1.5,
and ΔV=abs(VB−VCEA) and
λ is the wavelength of the resonator.
